(19) United States
(12) Patent Application Publication
(10) Pub. No.: US 2024/0194579 A1
(43) Pub. Date: Jun. 13, 2024

(54) ELECTRONIC COMPONENT MODULE

(71) Applicant: Murata Manufacturing Co., Ltd., Kyoto (JP)

(72) Inventors: Yoshifumi SAITO, Kyoto (JP); Yoshinori KIN, Kyoto (JP); Tomoki YAMAMOTO, Kyoto (JP); Yoshiki TOBITA, Kyoto (JP)

(21) Appl. No.: 18/444,982

(22) Filed: Feb. 19, 2024

Related U.S. Application Data
(63) Continuation of application No. PCT/JP2022/027550, filed on Jul. 13, 2022.

(30) Foreign Application Priority Data
Aug. 20, 2021 (JP) 2021-135122

(51) Int. Cl. H01L 23/498; H01L 23/15; H01L 23/31; H01L 25/16

(52) U.S. Cl. CPC H01L 23/49838; H01L 23/15; H01L 23/3135; H01L 23/3142; H01L 23/49811; H01L 25/16

(57) ABSTRACT

An electronic component module with components mounted on both surfaces of a board, the electronic component module including: a circuit board including a first main surface and a second main surface; a first electronic component mounted on the first main surface; a second electronic component mounted on the second main surface; an electrode for input/output on the first main surface; a columnar electrode connected to the electrode for input/output; a sealing resin layer covering the first main surface; an insulating layer covering the first electronic component and the sealing resin layer; an input/output electrode on the insulating layer; and a conductor, wherein the columnar electrode 154 includes an end surface exposed from the sealing resin layer, and the input/output electrode is connected to the columnar electrode through the conductor.

### CROSS REFERENCE TO RELATED APPLICATION

This is a continuation of International Application No. PCT/JP2022/027550 filed on Jul. 13, 2022 which claims priority from Japanese Patent Application No. 2021-135122 filed on Aug. 20, 2021. The contents of these applications are incorporated herein by reference in their entireties.

### BACKGROUND OF THE DISCLOSURE

### Field of the Disclosure

The present disclosure relates to an electronic component module.

### Description of the Related Art

Patent Literatures 1 and 2 each disclose an electronic component module with electronic components mounted on one or both surfaces of a board.
Patent Literature 1: WO 2015/098793
Patent Literature 2: JP 2012-33885 A

### BRIEF SUMMARY OF THE DISCLOSURE

In the electronic component modules disclosed in Patent Literatures 1 and 2, the top surfaces of electronic components mounted on the board are covered with a sealing resin.

Nowadays, in order to slim down the module as a whole, grinding may be performed on the top surfaces of electronic components, particularly the top surface of an integrated circuit (IC), mounted on a surface that is one of the main surfaces of the circuit board and that is adjacent to input/output electrodes of the electronic component module. In this case, scratches from grinding may cause cracks upon impact in the post-process, and the cracks may lead to destruction of the electronic components, particularly the IC.

The present disclosure was made to solve the above issue and aims to provide an electronic component module capable of preventing or reducing destruction of electronic components mounted on a circuit board even when the top surfaces of the electronic components are ground after mounting.

The electronic component module of the present disclosure is an electronic component module with components mounted on both surfaces of a board, the electronic component module including: a circuit board including a first main surface and a second main surface; a first electronic component mounted on the first main surface; a second electronic component mounted on the second main surface; an electrode for input/output on the first main surface; a columnar electrode connected to the electrode for input/output; a sealing resin layer covering the first main surface; an insulating layer covering the first electronic component and the sealing resin layer; an input/output electrode on the insulating layer; and a conductor, wherein the columnar electrode includes an end surface exposed from the sealing resin layer, and the input/output electrode is connected to the columnar electrode through the conductor.

The present disclosure can provide an electronic component module capable of preventing or reducing destruction of electronic components mounted on a circuit board even when the top surfaces of the electronic components are ground after mounting.

### BRIEF DESCRIPTION OF THE SEVERAL VIEWS OF THE DRAWINGS

FIG. 1 is a schematic cross-sectional view of an example of an electronic component module of the present disclosure (first embodiment).

FIG. 2 is a schematic plan view of an example layout of an input/output electrode and a third electronic component of the electronic component module of the present disclosure (first embodiment).

FIG. 3 is a schematic cross-sectional view of an example of an electronic component module according to a comparative embodiment.

FIG. 4 is a schematic plan view of a columnar electrode formation surface of the electronic component module in FIG. 3.

FIG. 5 is another cross-sectional view of another example of the electronic component module in FIG. 1, and shows a case where no third electronic component is mounted on a first main surface of an LTCC substrate.

FIG. 6 is a schematic plan view of a columnar electrode formation surface of the electronic component module in FIG. 5.

FIG. 7 is a schematic cross-sectional view of an example of the electronic component module of the present disclosure (first embodiment) during production, and shows mounting of the first electronic component and the third electronic component.

FIG. 8 is a schematic cross-sectional view of an example of the electronic component module of the present disclosure (first embodiment) during production, and shows sealing with a first resin.

FIG. 9 is a schematic cross-sectional view of an example of the electronic component module of the present disclosure (first embodiment) during production, and shows grinding of the resin layer.

FIG. 10 is a schematic cross-sectional view of an example of the electronic component module of the present disclosure (first embodiment) during production, and shows forming of an insulating layer.

FIG. 11 is a schematic cross-sectional view of an example of the electronic component module of the present disclosure (first embodiment) during production, and shows forming of via holes in the insulating layer.

FIG. 12 is a schematic cross-sectional view of an example of the electronic component module of the present disclosure (first embodiment) during production, and shows forming of vias and input/output electrodes.

FIG. 13 is a schematic cross-sectional view of an example of the electronic component module of the present disclosure (first embodiment) during production, and shows mounting of a second electronic component and a fourth electronic component.

FIG. 14 is a schematic cross-sectional view of an example of the electronic component module of the present disclosure (first embodiment) during production, and shows sealing with a second resin.

FIG. 15 is a schematic cross-sectional view of an example of the electronic component module of the present disclosure (first embodiment) during production, and shows forming of a metal conductor.

FIG. 16 is a schematic cross-sectional view of an example of an electronic component module of the present disclosure (second embodiment).

FIG. 17 is a schematic cross-sectional view of an example of an electronic component module of the present disclosure (third embodiment).

FIG. 18 is a schematic cross-sectional view of an example of an electronic component module of the present disclosure (fourth embodiment).

FIG. 19 is a schematic cross-sectional view of an example of an electronic component module of the present disclosure (fifth embodiment).

FIG. 20 is a schematic cross-sectional view of an example layout of a columnar electrode of the electronic component module of the present disclosure (fifth embodiment).

FIG. 21 is a schematic cross-sectional view of an example of an electronic component module of the present disclosure (sixth embodiment).

FIG. 22 is a schematic cross-sectional view of an example of an electronic component module of the present disclosure (seventh embodiment).

### DETAILED DESCRIPTION OF THE DISCLOSURE

Hereinafter, an electronic component module of the present disclosure is described.

The present disclosure is not limited to the following preferred embodiments, and may be suitably modified without departing from the gist of the present disclosure. Combinations of two or more preferred features described in the following preferred embodiments are also within the scope of the present disclosure.

### First Embodiment

An electronic component module according to a first embodiment has a package structure in which predetermined electronic components are mounted on both surfaces of a circuit board. The electronic component module includes an insulating layer on a sealing resin layer adjacent to input/output electrodes of the circuit board, and the input/output electrodes are led out from the circuit board to the insulating layer.

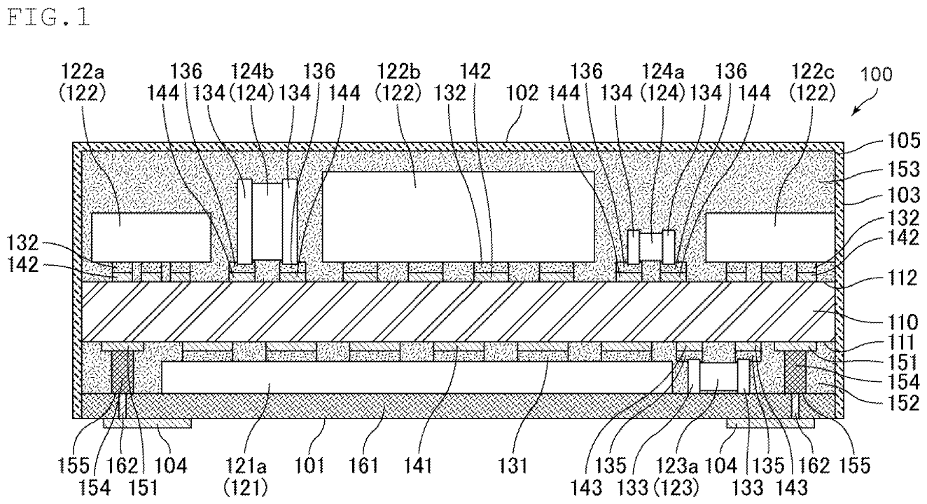

FIG. 1 is a schematic cross-sectional view of an example of an electronic component module of the present disclosure (first embodiment).

An electronic component module 100 shown in FIG. 1 is a module having a substantially rectangular cuboidal shape and including a mounting surface 101, a top surface 102 opposite to the mounting surface 101, and four side surfaces 103 interconnecting the mounting surface 101 and the top surface 102. The mounting surface 101 is provided with multiple input/output electrodes (I/O electrodes) 104 to be connected to other electronic components and boards (e.g., a motherboard). The other surfaces excluding the mounting surface 101, i.e., the top surface 102 and four side surfaces 103, are made of metal conductor layers (shielding electrodes) 105 for blocking electromagnetic waves.

The electronic component module 100 is an electronic component module with components mounted on both surfaces of a board, and internally includes, as a circuit board, a low-temperature co-fired ceramic substrate (hereinafter, “LTCC substrate”) 110 including a first main surface 111 adjacent to the mounting surface 101 and a second main surface 112 adjacent to the top surface 102, a first electronic component 121 mounted on the first main surface 111, and multiple second electronic components 122 mounted on the second main surface 112.

The first electronic component 121 includes a mounting surface provided with multiple Cu pillar bumps 131 as external terminals.

Each second electronic component 122 also includes a mounting surface provided with multiple Cu pillar bumps 132 as external terminals.

The LTCC substrate 110 is a multilayer ceramic substrate in which insulating layers (at least one insulating layer may include a via) and conductor layers including wires and electrodes are laminated together. Examples of materials of the conductor layers and vias include metal materials such as silver or copper. Examples of insulating materials of the insulating layer include low-temperature sintered ceramic materials. The low-temperature sintered ceramic materials are a type of ceramic material. It is a material that can be sintered simultaneously with silver and copper used as metal materials at a sintering temperature of 1000° C. or lower. Examples include those containing SiO₂—CaO—Al₂O₃—B₂O₃-based glass ceramic or SiO₂—MgO—Al₂O₃—B₂O₃-based glass ceramic.

The first main surface 111 of the LTCC substrate 110 is provided with multiple first electrodes (mounting pads) 141 in one-to-one correspondence with Cu pillar bumps 131 (external terminals) of the first electronic component 121. The first electronic component 121 is flip-chip mounted on the first main surface 111 as a result of connection of each Cu pillar bump 131 to its corresponding first electrode 141.

Each first electrode 141 is connected to its corresponding wire (not shown) of the LTCC substrate 110.

The first electronic component 121 is not limited but is preferably an electronic component including a mounting surface provided with multiple external terminals. Here, a surface mount type electronic component including the multiple Cu pillar bumps 131 as external terminals is mounted.

The first electronic component 121 is preferably an integrated circuit (IC). Here, a silicon on insulator (SOI) 121a is mounted. Alternatively, the first electronic component 121 may be, for example, a GaAs IC, a Si IC, a SiC IC, or the like.

It suffices as long as at least one first electronic component 121 is mounted on the first main surface 111 of the LTCC substrate 110. Multiple first electronic components 121 may be mounted thereon.

The second main surface 112 of the LTCC substrate 110 is provided with multiple second electrodes (mounting pads) 142 in one-to-one correspondence with the Cu pillar bumps 132 (external terminals) of each second electronic component 122. Each second electronic component 122 is flip-chip mounted on the second main surface 112 as a result of connection of each Cu pillar bump 132 to its corresponding second electrode 142.

Each second electrode 142 is connected to its corresponding wire (not shown) of the LTCC substrate 110.

Each second electronic component 122 is not limited but is preferably an electronic component including a mounting surface provided with multiple external terminals. Here, a surface mount type electronic component including the multiple Cu pillar bumps 132 as external terminals is mounted.

The second electronic components 122 are preferably ICs. Here, a heterojunction bipolar transistor (HBT) IC 122a, a surface acoustic wave (SAW) filter 122b, and a GaAs IC 122c are mounted.

A third electronic component 123 is mounted on the first main surface 111 of the LTCC substrate 110. The third electronic component 123 includes a mounting surface, a top surface opposite to the mounting surface, and paired external electrodes 133, instead of Cu pillar bumps (external terminals), as multiple external electrodes.

The paired external electrodes 133 are connected to the LTCC substrate 110. Here, each external electrode 133 is on a total of five surfaces, extending from the mounting surface to the top surface through the three side surfaces of the third electronic component 123.

More specifically, the first main surface 111 is provided with multiple third electrodes 143. The third electrodes 143 are in one-to-one correspondence with the paired external electrodes 133 of the third electronic component 123. The third electronic component 123 is mounted on the first main surface 111 as a result of connection of each external electrode 133 to its corresponding third electrode 143. Each external electrode 133 is connected to its corresponding third electrode 143 with, for example, solder 135. The third electronic component 123 is not limited. Here, for example, a chip capacitor 123a is mounted.

Each third electrode 143 is connected to its corresponding wire (not shown) of the LTCC substrate 110.

FIG. 1 shows a case where only one third electronic component 123 is mounted, but multiple third electronic components 123 may be similarly mounted on the first main surface 111 of the LTCC substrate 110.

Further, multiple fourth electronic components 124 each including paired external electrodes 134 instead of Cu pillar bumps (external terminals) are mounted on the second main surface 112 of the LTCC substrate 110.

More specifically, the second main surface 112 is provided with multiple fourth electrodes 144. The fourth electrodes 144 are in one-to-one correspondence with the paired external electrodes 134 of each fourth electronic component 124. Each fourth electronic component 124 is mounted on the second main surface 112 as a result of connection of each external electrode 134 to its corresponding fourth electrode 144. Each external electrode 134 is connected to its corresponding fourth electrode 144 with, for example, solder 136. The fourth electronic components 124 are not limited. Here, for example, a chip capacitor 124a and a chip inductor 124b are mounted.

Each fourth electrode 144 is connected to its corresponding wire (not shown) of the LTCC substrate 110.

A sealing resin layer 153 covering the second electronic components 122 and the fourth electronic components 124 are on the second main surface 112 of the LTCC substrate 110.

It suffices as long as at least one second electronic component 122 is mounted on the second main surface 112 of the LTCC substrate 110. Electronic components other than the second electronic components 122, for example, at least one of the fourth electronic components 124, may be omitted.

The electronic component module 100 includes multiple electrodes for input/output 151 on the first main surface 111 of the LTCC substrate 110, multiple columnar electrodes 154 connected to the multiple electrodes for input/output 151, and a sealing resin layer 152 covering the first main surface 111 of the LTCC substrate 110.

The columnar electrodes 154 are in one-to-one correspondence with the electrodes for input/output 151. The sealing resin layer 152 surrounds the first electronic component 121, the third electronic component 123, and the columnar electrodes 154.

Each columnar electrode 154 includes an end surface 155 exposed from the sealing resin layer 152.

The electronic component module 100 includes an insulating layer 161 covering the first electronic component 121, the third electronic component 123, and the sealing resin layer 152, and multiple vias 162 that allow the multiple columnar electrodes 154 to be electrically conductive to multiple input/output electrodes 104. The multiple input/output electrodes 104 are on the insulating layer 161 and connected to the multiple columnar electrodes 154 through the multiple vias 162.

The vias 162 are an example of “the conductor” of the electronic component module of the present disclosure and are on the insulating layer 161.

Preferably, the insulating layer 161 is an insulating layer made of resin, i.e., a resin insulating layer, or may be one (planarization layer) that forms a substantially flat surface by absorbing irregularities of the base. The insulating layer 161 may be made of any material, but a material that is fluid before curing or the like is preferred. Examples include curable resin materials such as a thermosetting epoxy resin and a polyimide resin, and thermoplastic polymers such as liquid crystal polymers.

The insulating layer 161, excluding portions where the vias 162 are formed, covers its underneath components, i.e., the first electronic component 121, the third electronic component 123, the columnar electrodes 154, and the sealing resin layer 152.

In other words, the insulating layer 161 is in contact with the top surface of the first electronic component 121 and is also in contact with the top surface of the third electronic component 123.

The insulating layer 161, the vias such as the vias 162 in the insulating layer 161 and the electrodes such as the input/output electrodes 104 on the insulating layer 161 function as redistribution layers.

The insulating layer 161 may not be in contact with the top surface of the third electronic component 123. In this case, the sealing resin layer 152 may be present between the insulating layer 161 and the third electronic component 123.

The electrodes such as the first electrodes 141 on the first main surface 111 of the LTCC substrate 110 and the electrodes such as the second electrodes 142 on the second main surface 112 of the LTCC substrate 110 are formed by firing simultaneously with a low-temperature sintered ceramic material. In contrast, the electrodes such as the input/output electrodes 104 on the insulating layer 161 are formed after the firing.

The input/output electrodes 104 are in one-to-one correspondence with the columnar electrodes 154. As described above, the columnar electrodes 154 are in one-to-one correspondence with the electrodes for input/output 151. In other words, the input/output electrodes 104 are also in one-to-one correspondence with the electrodes for input/output 151.

Each input/output electrode 104 is connected to its corresponding electrode for input/output 151 as a result of connection to its corresponding columnar electrode 154 through the via 162 in the insulating layer 161.

Here, one of end surfaces of each via 162 is connected to the end surface 155, which is exposed from the sealing resin layer 152, of the columnar electrode 154, and the other end surface of the via 162 is connected to the input/output electrode 104.

Usually, one via 162 is provided to each pair of the input/output electrode 104 and the columnar electrode 154, but multiple vias may be provided to each pair.

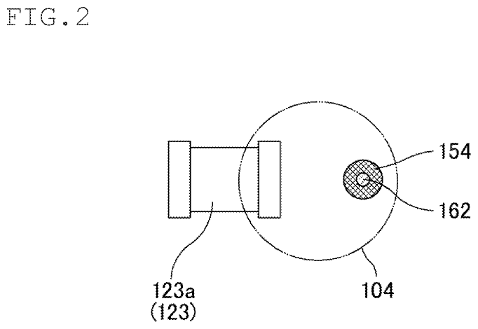

FIG. 2 is a schematic plan view of an example layout of the input/output electrode and the third electronic component of the electronic component module of the present disclosure (first embodiment).

As shown in FIG. 2, the third electronic component 123 overlaps the input/output electrode 104 in a plan view.

In FIG. 2, only a portion (here, only the end) of the third electronic component 123 overlaps the input/output electrode 104, but the entire third electronic component 123 may overlap the input/output electrode 104.

In this manner, a portion (or the entirety) of the top surface of the third electronic component 123 is opposite to the input/output electrode 104 across the insulating layer 161 as shown in FIG. 1.

As described above, the electronic component module 100 includes the insulating layer 161 covering the first electronic component 121 and the sealing resin layer 152, the vias 162 as conductors that allow the columnar electrodes 154 to be electrically conductive to the input/output electrodes 104, and the input/output electrodes 104 on the insulating layer 161. Each columnar electrode 154 includes the end surface 155 exposed from the sealing resin layer 152. The input/output electrodes 104 are connected to the columnar electrodes 154 through the vias 162. Thus, even when the top surface of the first electronic component 121 is ground after mounting in order to slim down the electronic component module 100 as a whole and scratches are made on the top surface (ground surface) of the first electronic component 121, the insulating layer 161 formed on the top surface of the first electronic component 121 can alleviate the stress on these scratches. This makes it possible to prevent or reduce generation and/or development of cracks from scratches upon impact in the post-process. Thus, destruction of the first electronic component 121 can be prevented or reduced.

The input/output electrodes 104 are on the insulating layer 161 not on the sealing resin layer 152, so that the input/output electrodes 104 can have improved adhesion to its base (the insulating layer 161), as compared to the case where the input/output electrodes 104 are on the sealing resin layer 152. This is because the insulating layer 161 can be material designed with a priority to adhesion to the input/output electrodes 104, while generally the sealing resin layer is material designed with specialization in sealing performance.

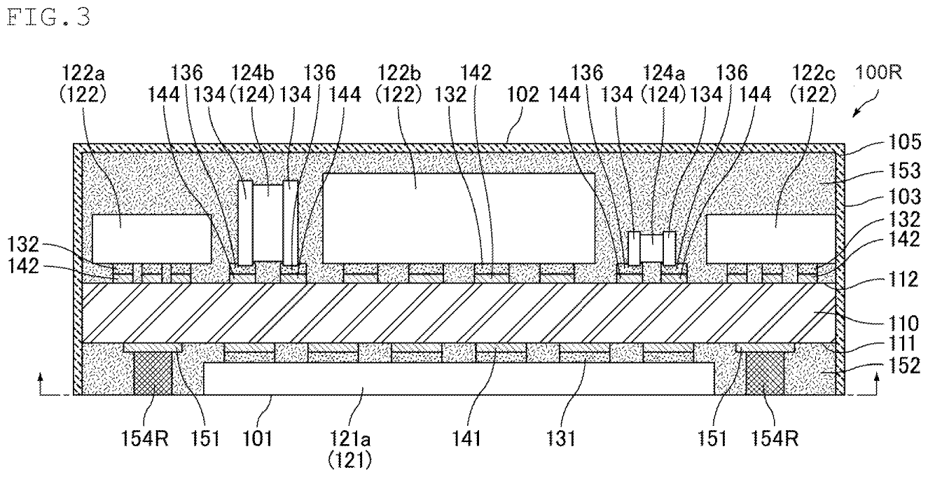

FIG. 3 is a schematic cross-sectional view of an example of an electronic component module according to a comparative embodiment.

An electronic component module 100R shown in FIG. 3 is substantially the same as the electronic component module 100 according to the first embodiment shown in FIG. 1 except that no insulating layer 161 is disposed and that columnar electrodes 154R are directly led out to the mounting surface 101 and function as input/output electrodes.

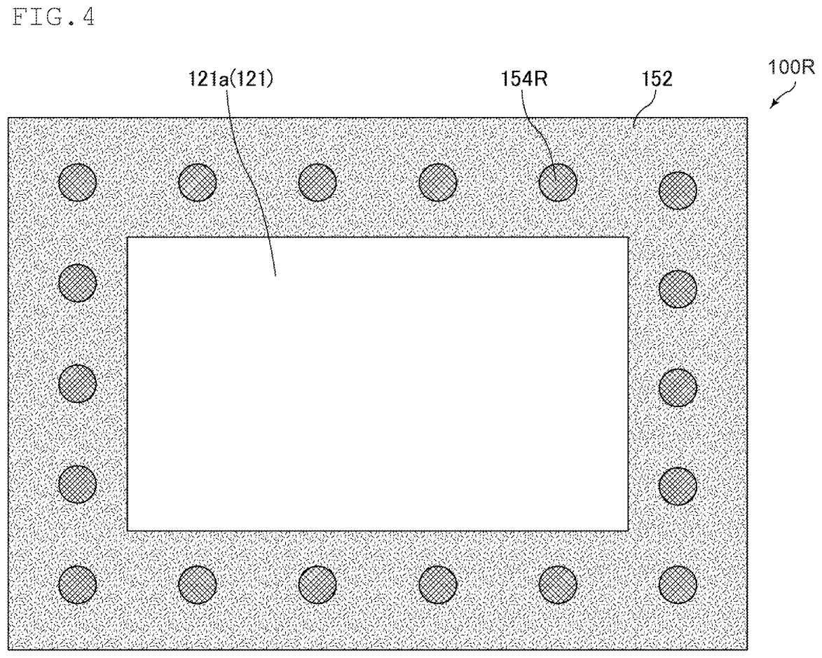

FIG. 4 is a schematic plan view of a columnar electrode formation surface (surface indicated by arrows in FIG. 3) of the electronic component module in FIG. 3.

Generally, the area of input/output electrodes is determined according to the size of a mounting pad of a component (e.g. a board such a motherboard) on which mounting is performed, and the area cannot be reduced voluntarily. Thus, as shown in FIG. 4, the electronic component module 100R, the layout area of the columnar electrodes 154R is large, and no components other than the first electronic component 121 can be mounted on the first main surface 111 of the LTCC substrate 110.

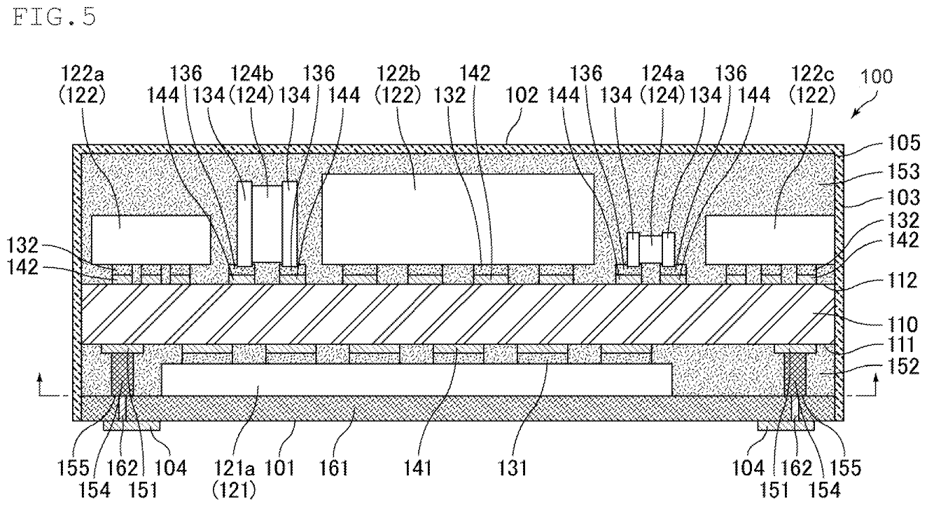

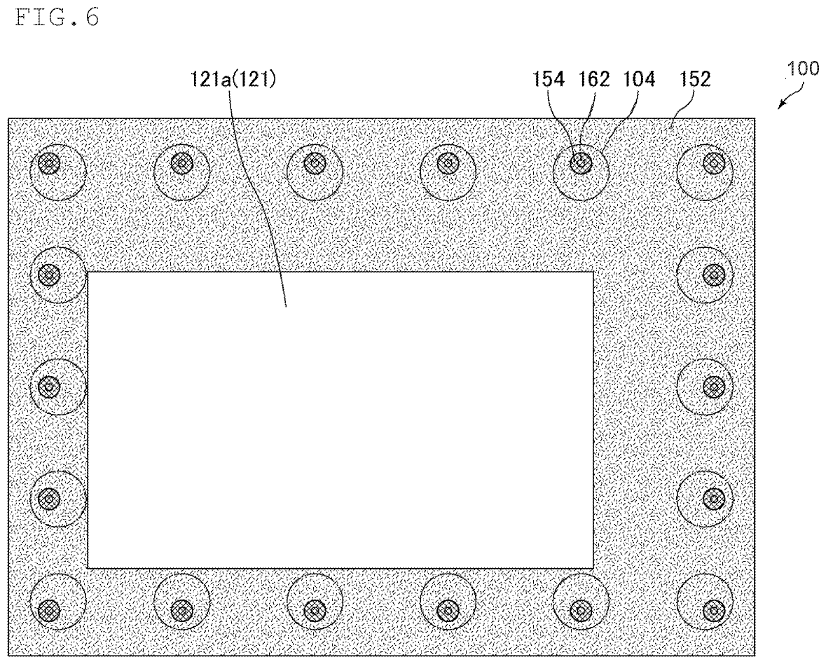

FIG. 5 is another cross-sectional view of another example of the electronic component module in FIG. 1, and shows a case where no third electronic component is mounted on the first main surface of the LTCC substrate. FIG. 6 is a schematic plan view of a columnar electrode formation surface (surface indicated by arrows in FIG. 5) of the electronic component module in FIG. 5.

As shown in FIG. 5 and FIG. 6, in the electronic component module 100, the cross-sectional area of each columnar electrode 154 in a plane parallel to the LTCC substrate 110 (or the mounting surface 101) is smaller than the plan view area of each input/output electrode 104.

Thus, the layout area of the columnar electrodes 154 and the vias 162 (conductors) can be reduced while providing the area required for the input/output electrodes 104. This makes it possible to provide a large footprint for components adjacent to the input/output electrodes 104 of the electronic component module 100, and as described above, the third electronic component 123 can be placed to overlap the input/output electrode 104. As a result, a component (here, the third electronic component 123) that cannot be mounted on the electronic component module 100R according to the comparative embodiment can also be mounted, and the electronic component module 100 can be downsized.

More specifically, as shown in FIG. 6, in a plan view, each columnar electrode 154 is positioned inside the region where its corresponding input/output electrode 104 (to which the columnar electrode 154 is connected) is placed.

The input/output electrodes 104 are connected/bonded, for example, to a board such as a motherboard with solder or the like.

The electronic component module 100 is produced by the following method, for example.

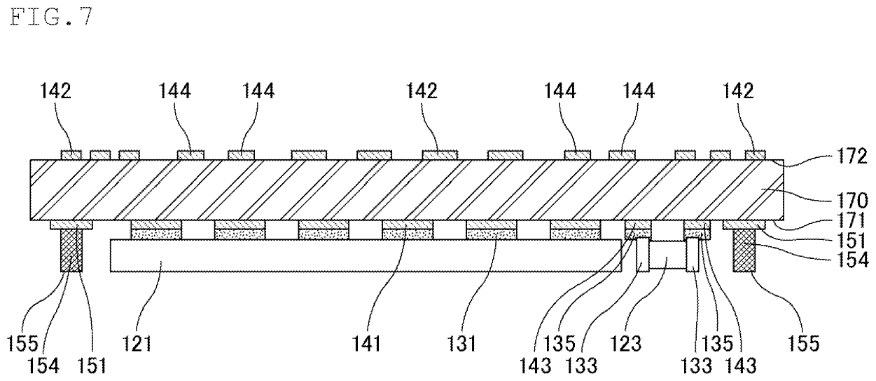

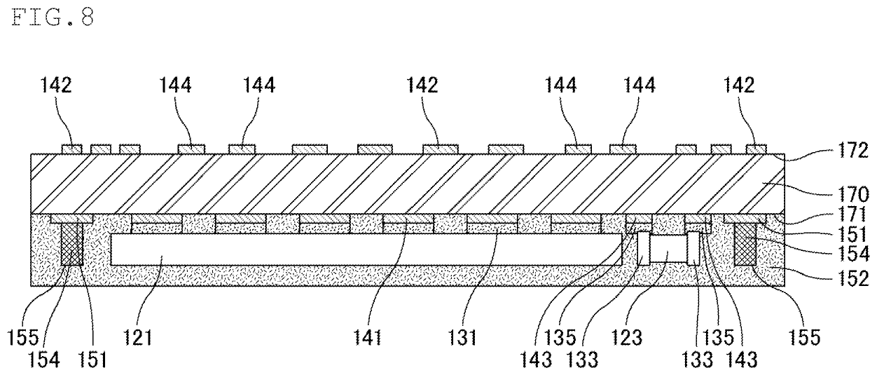

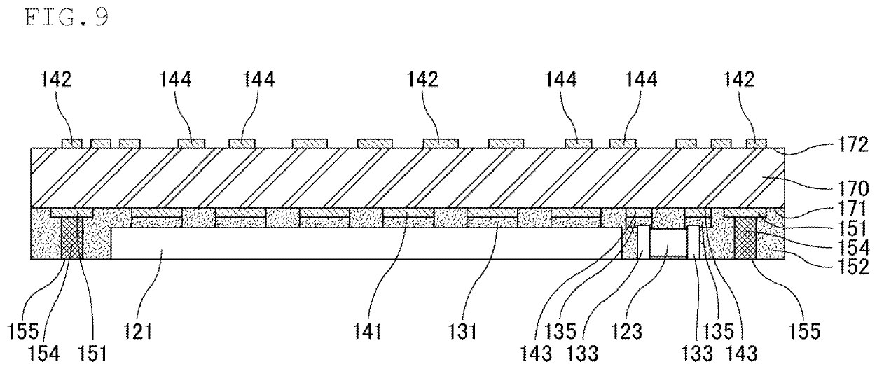

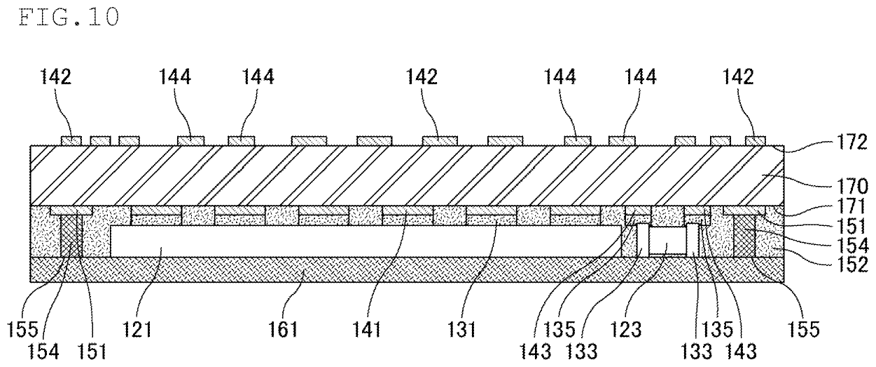

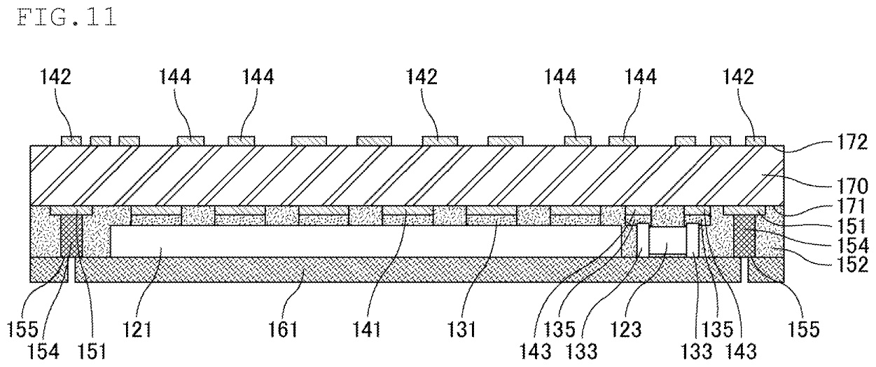

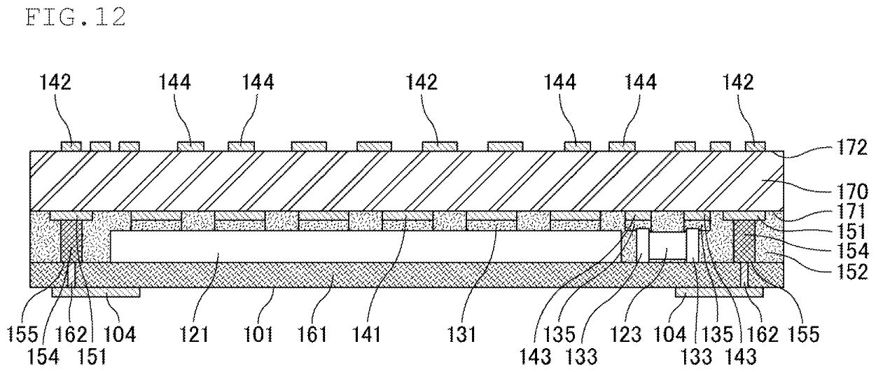

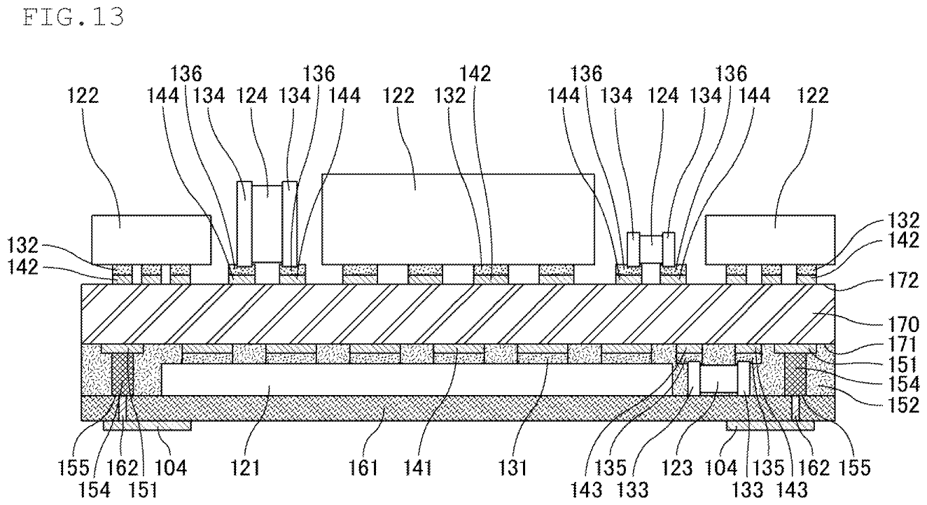

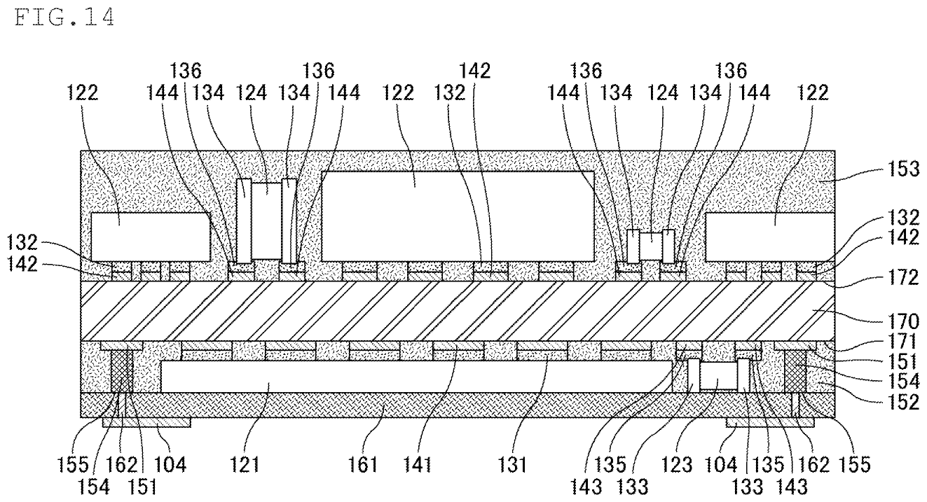

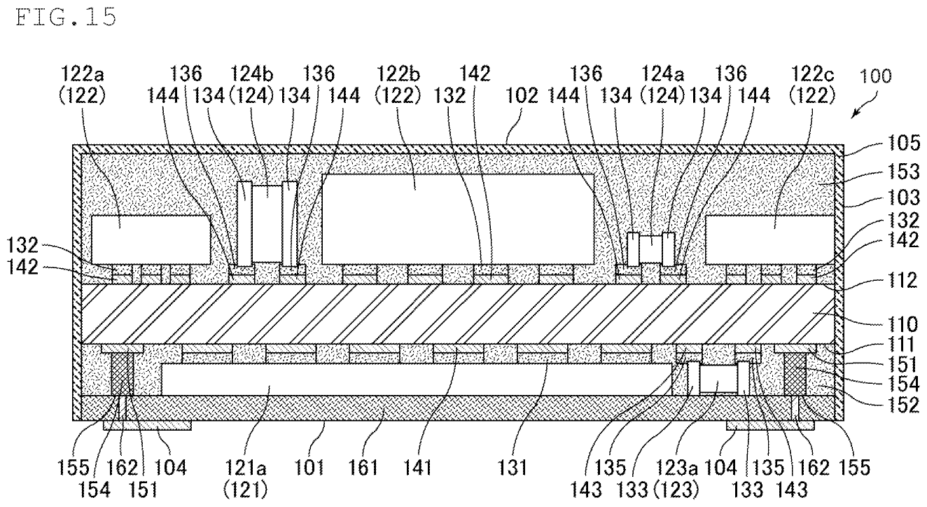

FIG. 7 to FIG. 15 are each a schematic cross-sectional view of an example of the electronic component module of the present disclosure (first embodiment) during production. FIG. 7 shows mounting of a first electronic component and a third electronic component. FIG. 8 shows sealing with a first resin. FIG. 9 shows grinding of a sealing resin layer. FIG. 10 shows forming of an insulating layer. FIG. 11 shows forming of via holes in the insulating layer. FIG. 12 shows forming of vias and input/output electrodes. FIG. 13 shows mounting of a second electronic component and a fourth electronic component. FIG. 14 shows sealing with a second resin. FIG. 15 shows forming of a metal conductor layer.

Hereinafter, an assembly board including multiple LTCC substrates is described. For the sake of convenience, FIG. 7 to FIG. 14 each show a singulated LTCC substrate as an assembly board.

First, as shown in FIG. 7, the first electronic component 121 including the multiple Cu pillar bumps 131 as external terminals and the third electronic component 123 are mounted and reflowed on a first main surface 171 (which corresponds to the first main surface 111 of the LTCC substrate 110) of the assembly board 170 including multiple LTCC substrates. In addition, Cu (copper) pins, for example, are formed as the columnar electrodes 154 on the electrodes for input/output 151.

Next, as shown in FIG. 8, the sealing resin layer 152 is formed on the first main surface 171 of the assembly board 170 to cover the first electronic component 121, the third electronic component 123, and the columnar electrodes 154.

Specifically, for example, a semi-cured sealing resin sheet (e.g., a sheet made of a thermosetting resin such as an epoxy resin) is placed on the first main surface 171, and the sealing resin is heated while being pressed with a plate for molding. Thus, the sealing resin is fluidized to fill in the space such as a gap between the first electronic component 121 and the assembly board 170, and the sealing resin is then cured.

Next, as shown in FIG. 9, the sealing resin layer 152 is ground to a predetermined thickness to expose the top surface of the first electronic component 121 and the end surface 155 of each columnar electrode 154. Here, the top surface of the third electronic component 123 may also be exposed. Alternatively, a top surface portion of the first electronic component 121 (and a top surface portion of the third electronic component 123) may be ground to thin the first electronic component 121 (and the third electronic component 123). For example, a semiconductor on the top surface portion of an IC as the first electronic component 121 may be ground.

Next, as shown in FIG. 10, the insulating layer 161 is formed on the first main surface 171 of the assembly board 170. As a result, the insulating layer 161 covering the first electronic component 121 and the like is formed.

Specifically, for example, a semi-cured sealing resin sheet (e.g., a sheet made of a thermosetting resin such as an epoxy resin) is placed on the first main surface 171, and a resin for insulating layer is heated while being pressed with a plate for molding. Thus, the resin for insulating layer is fluidized and then cured.

An uncured liquid resin for insulating layer (e.g., a thermosetting resin material such as an epoxy resin) may be printed or applied to the first main surface 171 with a dispenser, spin coater, or the like, and the resulting coat is leveled to be flat and then cured by heating with hot air or the like.

The thickness of the insulating layer 161 is not limited. For example, it may be 5 μm or more and 50 μm or less, 10 μm or more and 40 μm or less, or 15 μm or more and 30 μm or less.

The resin for insulating layer may contain a filler such as alumina, silica, silicon nitride, or aluminum hydroxide.

The average particle size of the filler in the resin for insulating layer may be, for example, 0.5 μm or more and less than 5 μm, 1 μm or more and 3 μm or less, or 1.5 μm or more and 2.5 μm or less, or may be 2 μm.

The filler content of the resin for insulating layer may be, for example, 20 wt % or more and 60 wt % or less, 30 wt % or more and 50 wt % or less, or 35 wt % or more and 45 wt % or less, or may be 40 wt % relative to the total amount of the resin for insulating layer.

Generally, the average particle size of the filler can be measured with a laser diffraction particle size distribution measuring device.

The linear expansion coefficient of the insulating layer 161 may be greater than the linear expansion coefficient of the LTCC substrate 110.

Generally, the linear expansion coefficient of the LTCC substrate is lower than the linear expansion coefficient of the board such as a motherboard on which mounting is performed. Thus, when the linear expansion coefficient of the insulating layer 161 is set higher than the linear expansion coefficient of the LTCC substrate 110, the following relationship can be satisfied: (Linear expansion coefficient of the LTCC substrate 110)<(Linear expansion coefficient of the insulating layer 161)<(Linear expansion coefficient of the board on which mounting is performed). Thus, the stress applied to the LTCC substrate 110 at the time of heat shock and drop impact can be alleviated, improving the shock or impact resistance of the electronic component module 100.

More specifically, the linear expansion coefficient of the insulating layer 161 at 25° C. may be, for example, 15 ppm/K or more and 40 ppm/K or less, 21 ppm/K or more and 35 ppm/K or less, or 25 ppm/K or more and 30 ppm/K or less.

The linear expansion coefficient of the LTCC substrate 110 at 25° C. may be, for example, 5 ppm/K or more and 12 ppm/K or less, 6 ppm/K or more and 11 ppm/K or less, or 7 ppm/K or more and 10 ppm/K or less.

From the same perspective as the linear expansion coefficient, the Young's modulus of the insulating layer 161 may be lower than the Young's modulus of the LTCC substrate 110.

Generally, the Young's modulus of the LTCC substrate is higher than the Young's modulus of the board such as a motherboard on which mounting is performed. Thus, when the Young's modulus of the insulating layer 161 is set lower than the Young's modulus of the LTCC substrate 110, the following relationship can be satisfied: (Young's modulus of the LTCC substrate 110)>(Young's modulus of the insulating layer 161)≥(Young's modulus of the board on which mounting is performed). Thus, also in this case, the stress applied to the LTCC substrate 110 at the time of heat shock and drop impact can be alleviated, improving the shock or impact resistance of the electronic component module 100.

More specifically, the Young's modulus of the resin for insulating layer at 25° C. may be, for example, 2 GPa or more and 20 GPa or less.

The Young's modulus of the LTCC substrate 110 at 25° C. may be, for example, 50 GPa or more and 100 GPa or less, 60 GPa or more and 90 GPa or less, or 70 GPa or more and 80 GPa or less.

Next, as shown in FIG. 11, via holes are formed in the insulating layer 161 by CO₂ laser or photolithography. Subsequently, the residual resin is removed by desmear.

Next, as shown in FIG. 12, the vias 162 as conductors are formed in the via holes in the insulating layer 161. At the same time, the input/output electrodes 104 are formed on the insulating layer 161.

Specifically, for example, first, a metal film (plating power feeding film) is formed on the surface of the insulating layer 161 by sputtering, and then, a plating film is formed in the via holes in the insulating layer 161 and on the surface of the insulating layer 161 by electrolytic plating. Subsequently, the input/output electrodes 104 are formed by patterning the plating film by photolithography.

The vias 162 may be made of a conductive paste.

Next, as shown in FIG. 13, the second electronic components 122 including the multiple Cu pillar bumps 132 as external terminals and other electronic components such as the fourth electronic components 124 are mounted and reflowed on a second main surface 172 (which corresponds to the second main surface 112 of the LTCC substrate 110) of the assembly board 170.

Next, as shown in FIG. 14, the sealing resin layer 153 is formed to cover the second electronic components 122 and other electronic components.

The sealing resin layer 153 can be formed in the same manner as the sealing resin layer 152. In other words, for example, a semi-cured sealing resin sheet (e.g., a sheet made of a thermosetting resin such as epoxy resin) is placed on the second main surface 172, and the sealing resin is heated while being pressed with a plate for molding. Thus, the sealing resin is fluidized to fill in the space such as a gap between the second electronic components 122 and the second main surface 172, and the sealing resin is then cured.

The sealing resins for the sealing resin layers 152 and 153 may contain a filler such as alumina, silica, silicon nitride, aluminum hydroxide, barium titanate, or titania.

The average particle size of the filler in each of the sealing resins for the sealing resin layers 152 and 153 may be, for example, 5 μm or more and 15 μm or less, 7 μm or more and 13 μm or less, or 9 μm or more and 11 μm or less, or may be 10 μm.

The sealing resins for the sealing resin layers 152 and 153 may each have a filler content of, for example, 70 wt % or more and 98 wt % or less relative to the total amount of the sealing resin.

The filler content of the resin for insulating layer may be lower than the filler content of each of the sealing resins for the sealing resin layers 152 and 153.

The sealing resins for the sealing resin layers 152 and 153 may each have a Young's modulus at 25° C. of, for example, 10 GPa or more and 30 GPa or less.

As described above, the Young's modulus of the resin for insulating layer at 25° C. may be lower than the Young's modulus of the sealing resins for the sealing resin layers 152 and 153 at 25° C.

The sealing resin for the sealing resin layer 152 may be the same as or different from the sealing resin for the sealing resin layer 153 in terms of materials and/or properties.

The sealing resins for the sealing resin layers 152 and 153 may be the same as, but preferably different from, the resin for insulating layer in terms of materials and properties.

Next, the assembly board 170 is cut at predetermined positions by a dicer or the like for singulation, whereby each LTCC substrate 110 is cut out.

Then, as shown in FIG. 15, the metal conductor layer 105 is formed on the surfaces excluding the mounting surface 101.

For example, the LTCC substrate 110 is placed on a tray for sputtering, with the mounting surface 101 facing down. Here, paste or tape may be attached to the mounting surface 101 in order to prevent a sputtered film from spreading thereto. An adhesion layer such as a stainless steel thin film (having a thickness of 0.15 μm, for example) is formed by sputtering on the surfaces excluding the mounting surface 101, and subsequently, a conductive layer such as a coper thin film (having a thickness of 2 pam, for example) is sequentially formed thereon, whereby the metal conductor layer 105 is formed.

The metal conductor layer 105 may have a multilayer structure including an adhesion layer, a corrosion resistant layer, and the like in addition to a conductive layer as described above, or may have a monolayer structure consisting of a conductive layer.

Thus, the electronic component module 100 according to the first embodiment is produced.

### Second Embodiment

The present embodiment is different from the first embodiment in that the electronic component module includes, as a third electronic component, an electronic component having a structure in which its external electrode is not opposite to an input/output electrode across the insulating layer.

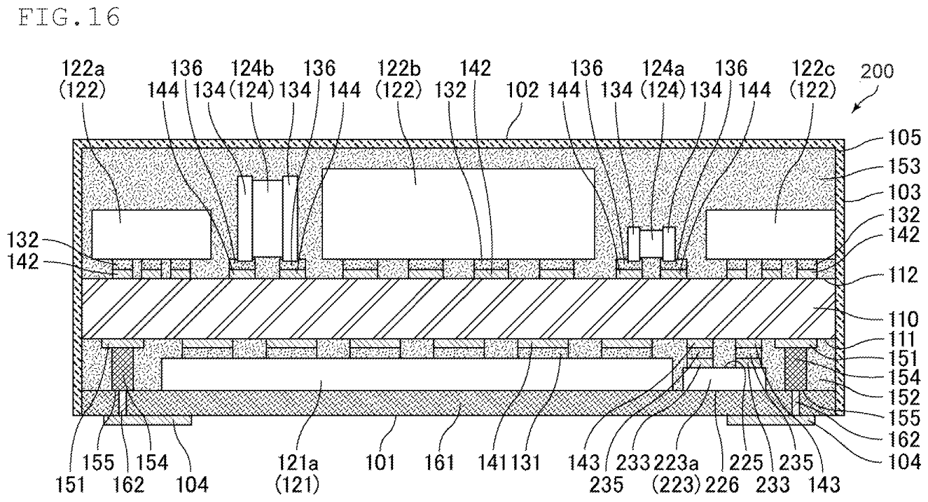

FIG. 16 is a schematic cross-sectional view of an example of an electronic component module of the present disclosure (second embodiment).

An electronic component module 200 shown in FIG. 16 includes a third electronic component 223 instead of the third electronic component 123 of the first embodiment.

As in the third electronic component 123, the third electronic component 223 includes a mounting surface 225, a top surface 226 opposite to the mounting surface 225, and paired external electrodes 233, instead of Cu pillar bumps (external terminals), as multiple external electrodes connected to the LTCC substrate 110.

In the first embodiment, the electronic component module includes the third electronic component 123 in which one of the external electrodes 133 is at a position opposite to the input/output electrode 104 across the insulating layer 161. In this case, parasitic capacitance may occur at the position. Due to the parasitic capacitance, feedback to the IC may take more time and the IC may have poor stability in operation.

In contrast, in the present embodiment, the electronic component module includes the third electronic component 223 in which the external electrodes 233 are not at positions opposite to the input/output electrode 104 across the insulating layer 161. In other words, the paired external electrodes 233 of the third electronic component 223 are on the mounting surface 225 but not on the top surface 226.

Thus, generation of unnecessary parasitic capacitance can be prevented, resulting in stable properties, such as more stable IC operation.

Each external electrode 233 is not on either the top surface 226 or three side surfaces of the third electronic component 223, but it is on only the mounting surface 225.

The third electronic component 223 is mounted on the first main surface 111 as a result of connection of each external electrode 233 to its corresponding third electrode 143. Each external electrode 233 is connected to its corresponding third electrode 143 with, for example, solder 235. The third electronic components 223 are not limited. Here, for example, a chip capacitor 223a is mounted.

The electronic component module 200 is produced by the same method as the electronic component module 100, for example.

### Third Embodiment

The present embodiment is different from the first or second embodiment in that the electronic component module includes multiple vias connected to input/output electrodes, that at least one of these multiple vias (usually, one) is connected to a columnar electrode, and that the other vias are not connected to columnar electrodes.

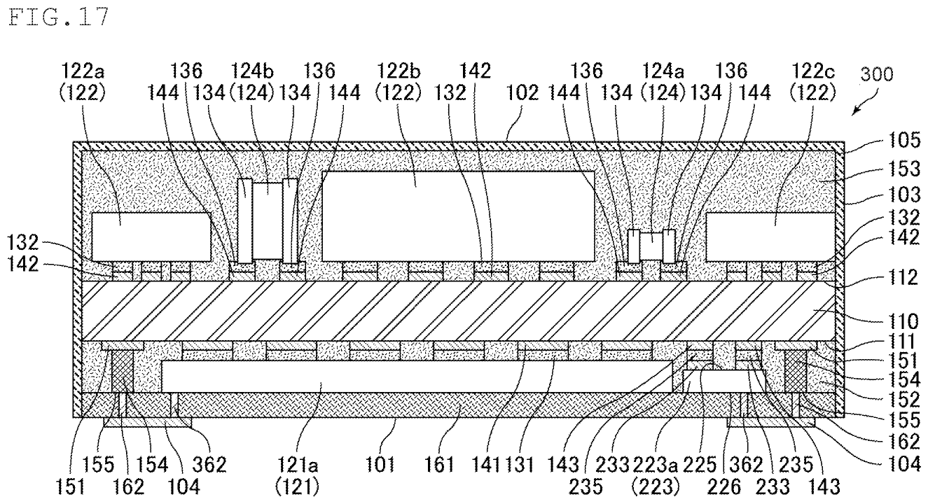

FIG. 17 is a schematic cross-sectional view of an example of an electronic component module of the present disclosure (third embodiment).

An electronic component module 300 shown in FIG. 17 further includes vias 362 in the insulating layer 161 and connected to the input/output electrodes 104 but not to the columnar electrodes 154.

In the first or second embodiment, due to temperature changes in the electronic component module mounted on the board such as a motherboard, stress may be applied to the interface between the input/output electrodes 104 and the insulating layer 161 or to the vias 162 connected to the columnar electrodes 154, possibly leading to destruction of an input/output electrode portion of the electronic component module.

In contrast, in the present embodiment, the electronic component module further includes the vias 362 connected to the input/output electrodes 104 but not to the columnar electrodes 154, in addition to the vias 162 (as conductors) connected to the columnar electrodes 154 and the input/output electrodes 104. In other words, more vias are connected to the input/output electrodes 104. This can improve the adhesion of the interface between the input/output electrodes 104 and the insulating layer 161 (the bonding strength of the input/output electrodes 104). This, as a result, can prevent or reduce destruction of an input/output electrode portion of the electronic component module 300 due to temperature changes after mounting of the electronic component module 300 on the board such as a motherboard.

Preferably, the vias 362 are electrically connected only to the input/output electrodes 104. Specifically, for example, as shown in FIG. 17, preferably, the vias 362 are bonded to an insulator, such as ceramics, defining a top surface of the third electronic component 223 (e.g., the chip capacitor 223a) described in the second embodiment. The vias 362 may be bonded to a semiconductor defining the top surface of the IC as the first electronic component 121.

The electronic component module 300 is produced by the same method as the electronic component module 100, for example.

### Fourth Embodiment

In the present embodiment, the layout of the vias connected to the columnar electrodes is different from that in the first to third embodiments. In the present embodiment, each via is disposed along a side surface of each columnar electrode.

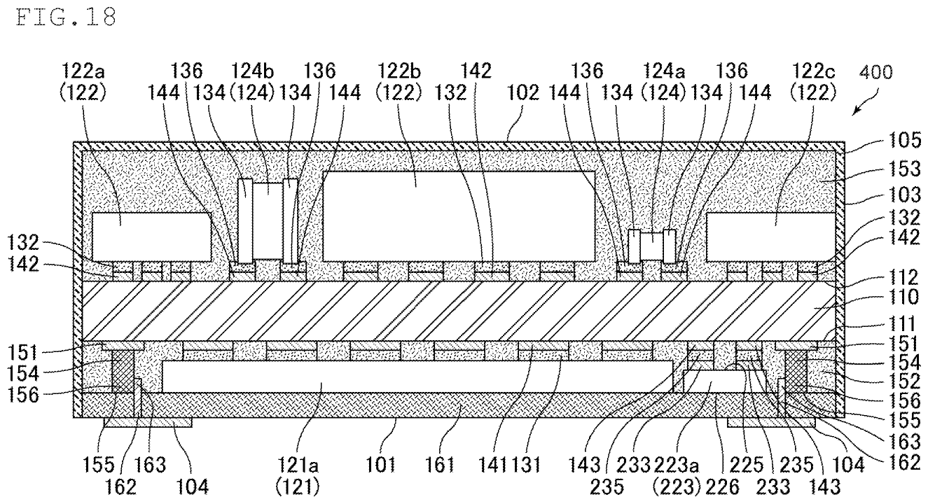

FIG. 18 is a schematic cross-sectional view of an example of an electronic component module of the present disclosure (fourth embodiment).

In an electronic component module 400 shown in FIG. 18, the vias 162 as conductors that connect the input/output electrodes 104 to the columnar electrodes 154 are in the sealing resin layer 152 and the insulating layer 161. Each via 162 includes an end 163 along a side surface of the corresponding columnar electrode 154.

This makes it possible to increase the contact area between the columnar electrodes 154 and the vias 162, which, as a result, can improve the bonding strength between the columnar electrodes 154 and the vias 162. This, as a result, can prevent or reduce destruction of an input/output electrode portion of the electronic component module 400 due to temperature changes after mounting of the electronic component module 400 on the board such as a motherboard.

More specifically, the end 163 of each via 162 opposite to the input/output electrode 104 is embedded in the sealing resin layer 152. Each via 162 is connected to the corresponding columnar electrode 154 through connection between a side surface of the end 156 of the columnar electrode 154 opposite to the electrode for input/output 151 and a side surface of the end 163 of the via 162.

The electronic component module 400 is produced by the same method as the electronic component module 100, except that, for example, the via holes are formed through the insulating layer 161 to reach the inside of the sealing resin layer 152.

### Fifth Embodiment

The present embodiment is different from the first to fourth embodiments in the position of the end of each columnar electrode. In the present embodiment, the columnar electrodes extend to the middle (middle part) of the insulating layer.

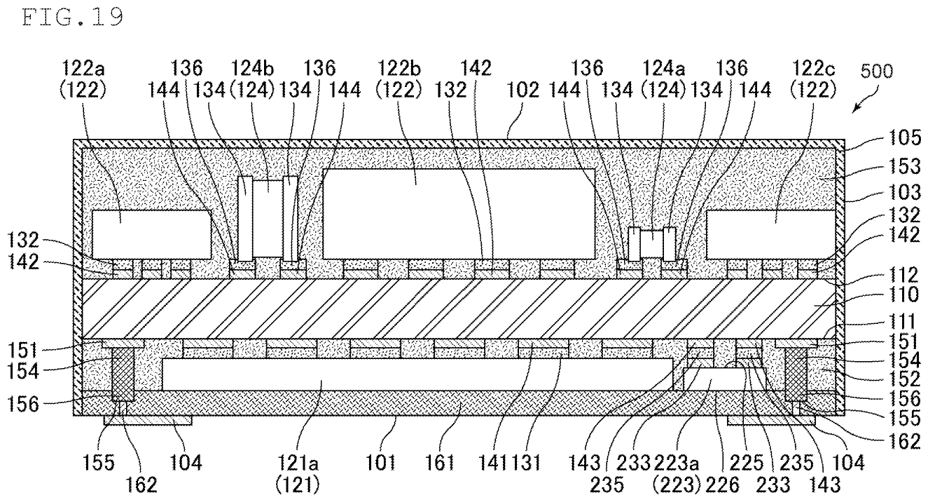

FIG. 19 is a schematic cross-sectional view of an example of an electronic component module of the present disclosure (fifth embodiment).

In an electronic component module 500 shown in FIG. 19, an end 156 of each columnar electrode 154 is embedded in the insulating layer 161.

This displaces the interface between the columnar electrodes 154 and the vias 162 from the interface between the sealing resin layer 152 and the insulating layer 161, so that the stress applied to the columnar electrodes 154 and the vias 162 can be alleviated. This, as a result, can prevent or reduce destruction of an input/output electrode portion of the electronic component module 500 due to temperature changes after mounting of the electronic component module 500 on the board such as a motherboard.

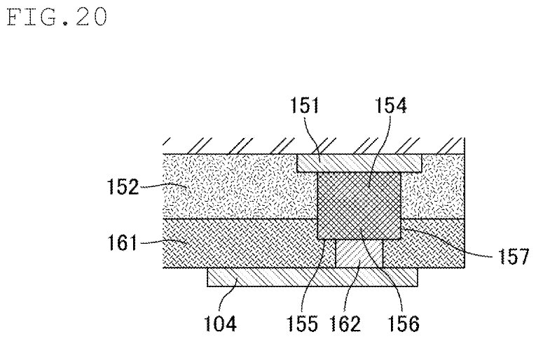

FIG. 20 is a cross-sectional plan view of an example layout of a columnar electrode of the electronic component module of the present disclosure (fifth embodiment).

In the present embodiment, as shown in FIG. 20, the end 156 of each columnar electrode 154 may be exposed from the sealing resin layer 152, and the end surface 155 and an end side surface 157 defining the end 156 of each columnar electrode 154 may be in contact with the insulating layer 161.

The electronic component module 500 is produced by the following method, for example.

First, the sealing resin layer 152 is ground to a predetermined thickness as in the first embodiment. Yet, the sealing resin layer 152 is ground until only the end surface 155 of each columnar electrode 154 is exposed but the first electronic component 121 is not exposed.

Subsequently, a slurry mixture of water and alumina abrasive grains is sprayed to the ground surface with air pressure. Thus, only the sealing resin layer 152 is selectively ground without grinding the columnar electrodes 154 to expose the top surface of the first electronic component 121 and the end 156 of each columnar electrode 154. Here, the top surface of the third electronic component 223 may also be exposed.

Thereafter, the same process as in the first embodiment is performed, whereby an electronic component module 600 can be produced.

### Sixth Embodiment

The present embodiment is different from the first to fifth embodiments in that a dummy electrode not electrically connected to the LTCC substrate serving as a circuit board is further on the insulating layer.

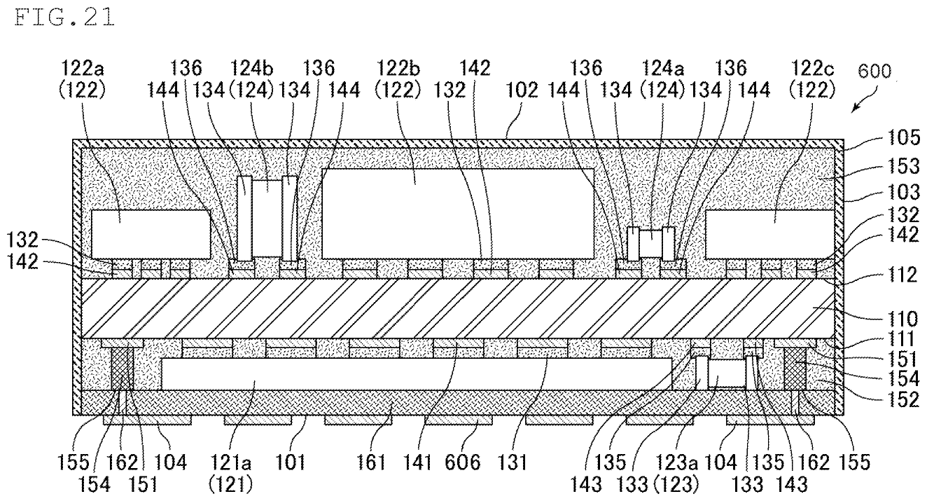

FIG. 21 is a schematic cross-sectional view of an example of an electronic component module of the present disclosure (sixth embodiment).

The electronic component module 600 shown in FIG. 21 further includes multiple dummy electrodes 606 on the insulating layer 161 and not electrically connected to the LTCC substrate 110.

Thus, the dummy electrodes 606, in addition to the input/output electrodes 104, can be bonded with solder or the like to the board such as a motherboard on which mounting is performed. Hence, the stress applied to the terminals (the input/output electrodes 104) at the time of heat shock and drop impact can be dispersed to the dummy electrodes 606, which can improve the shock or impact resistance of each terminal.

More specifically, each dummy electrode 606 is not electrically connected to the LTCC substrate 110 either directly or indirectly. It is a conductor layer in an electrically insulated state.

Preferably, the multiple dummy electrodes 606 are arranged regularly in two dimensions. For example, the multiple dummy electrodes 606 may be arrayed in a grid (matrix) shape or may be arrayed at the same pitch as the input/output electrodes 104.

The number of the dummy electrodes 606 is not limited as long as there is at least one, but as shown in FIG. 21, preferably, multiple dummy electrodes are present in terms of shock or impact resistance.

The electronic component module 600 is produced by the same method as the electronic component module 100, for example.

### Seventh Embodiment

The present embodiment is different from the sixth embodiment in that the IC as the first electronic component includes a top surface made of a metal layer and that the top surface is bonded to the dummy electrodes through the vias.

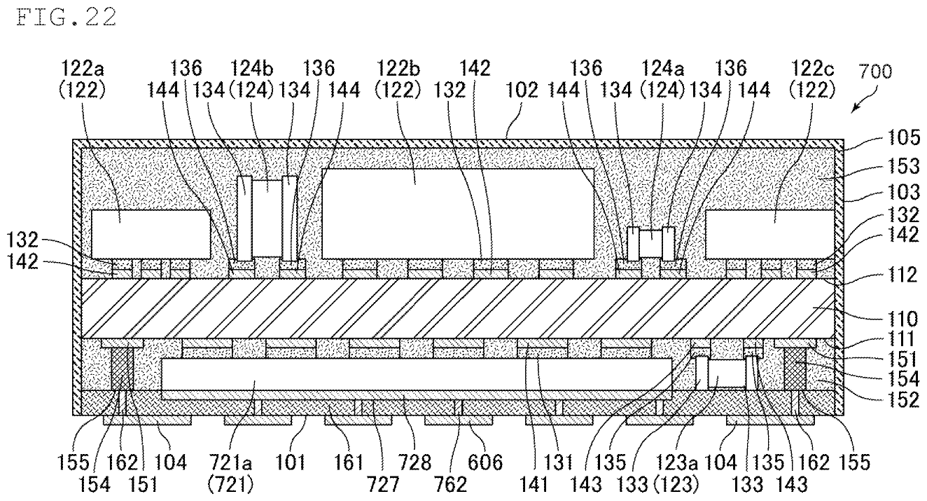

FIG. 22 is a schematic cross-sectional view of an example of an electronic component module of the present disclosure (seventh embodiment).

An electronic component module 700 shown in FIG. 22 includes a first electronic component 721 instead of the first electronic component 121 of the first embodiment.

The first electronic component 721 is an IC including a top surface 727 made of a metal layer 728. Here, for example, an SOI 721a is mounted.

The electronic component module 700 further includes vias 762 in the insulating layer 161 and bonded to the multiple dummy electrodes 606 described in the sixth embodiment and the top surface 727 of the IC.

Thus, the dummy electrodes 606 can be connected, with solder or the like, to the board such as a motherboard on which mounting is performed so as to allow heat generated from the IC to dissipate to the board such as a motherboard with a high heat capacity through the metal layer 728, the vias 762, and the dummy electrodes 606. In other words, this can improve the heat dissipation of the electronic component module 700. This, as a result, enables stable operation of the IC as the first electronic component 721.

This also achieves a similar effect (improvement in shock or impact resistance) as in the sixth embodiment.

The metal layer 728 may be made of any material, but a material with an excellent thermal conductivity is preferred. Examples include copper, aluminum, silver, and gold.

The thickness of the metal layer 728 is not limited and may be, for example, 1 μm or more and 15 μm or less, 2 μm or more and 10 μm or less, or 3 μm or more and 7 μm or less.

For example, the metal layer 728 can be formed by sputtering or electroless plating on a semiconductor such as silicon of the first electronic component 721 (IC).

The electronic component module 700 is produced by the following method, for example.

First, as in the first embodiment, the first electronic component 721 and the third electronic component 123 are mounted and reflowed, and the columnar electrodes 154 (e.g., Cu pins) are also formed on the electrodes for input/outputs 151.

Subsequently, as in the first embodiment, the sealing resin layer 152 is formed to cover the first electronic component 721, the third electronic component 123, and the columnar electrodes 154.

Further, the sealing resin layer 152 is ground to a predetermined thickness as in the first embodiment to expose a top surface of the first electronic component 721 and the end surface 155 of each columnar electrode 154. Here, the top surface of the third electronic component 123 may also be exposed. Alternatively, a top surface portion of the first electronic component 721 (and a top surface portion of the third electronic component 123) may be ground to thin the first electronic component 721 (and the third electronic component 123). For example, a semiconductor on the top surface portion of an IC as the first electronic component 721 may be ground.

Next, a metal film is formed on the entire substrate surface by sputtering or electroless plating the ground surface. Subsequently, a resist layer is formed on the metal film and subjected to exposure and development to keep only the metal layer 728 on the top surface of the IC as the first electronic component 721.

Then, as in the first embodiment, the insulating layer 161 is formed on the metal layer 728, via holes are made, and the vias 162 and 762, the input/output electrodes 104, and the dummy electrodes 606 are formed.

Thereafter, the same process as in the first embodiment is performed, whereby the electronic component module 700 can be produced.

The number of the vias 762 is not limited as long as there is at least one depending on the number of the dummy electrodes 606, but as shown in FIG. 22, preferably, multiple vias are present in terms of heat dissipation and shock or impact resistance.

In the present embodiment, the top surface of the IC as the first electronic component 721 is made of the metal layer 728. The ground surface of the IC is not directly covered with the insulating layer 161, but as in the first embodiment, it is possible to prevent or reduce generation and/or development of cracks from scratches on the ground surface.

The metal layer 728 is formed thin as described above. Thus, if the ground surface of the IC has scratches, the metal layer will be formed along the scratches. In other words, the scratches will not be filled with the metal layer 728, so that the structure can similarly alleviate the stress, with the insulating layer 161 filling the scratches.

The above embodiments were described with reference to the case where the LTCC substrate, which is a type of an inorganic material substrate, is used as a circuit board, but the circuit board of the electronic component module of the present disclosure is not limited as long as it is a printed wiring board (preferably, a multilayer board).

The inorganic material substrate is not limited as long as it is a circuit board (preferably, a multilayer board) containing an inorganic material (preferably, ceramic) as an insulating material.

The above embodiments were described with reference to the case where the vias 162 in at least the insulating layer 161 are used as conductors that allow the columnar electrodes to be electrically conductive to the input/output electrodes. Yet, the conductors of the electronic component module of the present disclosure are not limited as long as they are elements that allow the columnar electrodes to be electrically conductive to the input/output electrodes, i.e., elements that electrically interconnect the columnar electrodes and the input/output electrodes (a connection structure or a conductive member). For example, the conductors may be conductive fillers or the like that establish an electrical connection only in the direction where the columnar electrodes and the input/output electrodes are opposite to each other.

The above embodiments were described with reference to the case where the first electronic component 121 including a mounting surface provided with the multiple Cu pillar bumps 131 and the second electronic components 122 including a mounting surface provided with the multiple Cu pillar bumps 132 are mounted. Yet, the first electronic component and the second electronic component of the electronic component module of the present disclosure are not limited. They may be electronic components each including a mounting surface provided with multiple external terminals. More specifically, they may be, for example, electronic components (preferably, ICs) with land grid array (LGA) structures or electronic components (preferably, ICs) with ball grid array (BGA) structures.

In the case of electronic components with LGA structures, each external terminal (land) may be connected to the circuit board with solder.

In either case, usually, the multiple external terminals include three or more external terminals that are arrayed regularly at an equal pitch only on the mounting surface. For example, the external terminals may be arrayed, for example, in an annular shape such as a rectangular shape on the mounting surface or may be arrayed in a grid (matrix) shape on the mounting surface.
100, 200, 300, 400, 500, 600, 700 electronic component module
101 mounting surface of electronic component module
102 top surface of electronic component module
103 side surface of electronic component module
104 input/output electrode
105 metal conductor layer
110 low-temperature co-fired ceramic substrate
111 first main surface of low-temperature co-fired ceramic substrate
112 second main surface of low-temperature co-fired ceramic substrate
121, 721 first electronic component
121a, 721a SOI
122 second electronic component
122a HBT IC
122b SAW filter
122c GaAs IC
123, 223 third electronic component
123a, 124a, 223a chip capacitor
124 fourth electronic component
124b chip inductor
131, 132 Cu pillar bump
133, 134, 233 external electrode
135, 136, 235 solder
141 first electrode
142 second electrode
143 third electrode
144 fourth electrode
151 electrode for input/output
152, 153 sealing resin layer
154 columnar electrode
155 end surface of columnar electrode
156 end of columnar electrode
157 end side surface of columnar electrode
161 insulating layer
162, 362, 762 via
163 end of via
170 assembly board
171 first main surface of assembly board
172 second main surface of assembly board
225 mounting surface of third electronic component
226 top surface of third electronic component
606 dummy electrode
727 top surface of first electronic component
728 metal layer of first electronic component

1. An electronic component module with components mounted on both surfaces of a board, the electronic component module comprising:
a circuit board including a first main surface and a second main surface;
a first electronic component mounted on the first main surface;
a second electronic component mounted on the second main surface;
an electrode for input/output on the first main surface;
a columnar electrode connected to the electrode for input/output;
a sealing resin layer covering the first main surface;
an insulating layer covering the first electronic component and the sealing resin layer;
an input/output electrode on the insulating layer; and
a conductor,
wherein the columnar electrode includes an end surface exposed from the sealing resin layer, and
the input/output electrode is connected to the columnar electrode through the conductor.

2. The electronic component module according to claim 1,
wherein a cross-sectional area of the columnar electrode in a plane parallel to the circuit board is smaller than a plan view area of the input/output electrode,
the electronic component module further includes a third electronic component mounted on the first main surface and covered with the insulating layer, and
the third electronic component overlaps the input/output electrode in a plan view.

3. The electronic component module according to claim 2,
wherein the third electronic component includes a mounting surface, a top surface opposite to the mounting surface, and multiple external electrodes connected to the circuit board, and
the multiple external electrodes are on the mounting surface but not on the top surface.

4. The electronic component module according to claim 1, further comprising a via in the insulating layer and connected to the input/output electrode but not to the columnar electrode.

5. The electronic component module according to claim 1,
wherein the conductor is a via in each of the sealing resin layer and the insulating layer and includes an end along a side surface of the columnar electrode.

6. The electronic component module according to claim 1,
wherein the columnar electrode includes an end embedded in the insulating layer.

7. The electronic component module according to claim 1, further comprising a dummy electrode on the insulating layer and not electrically connected to the circuit board.

8. The electronic component module according to claim 1,
wherein the first electronic component is an integrated circuit.

9. The electronic component module according to claim 7,
wherein the first electronic component is an integrated circuit including a top surface comprising a metal layer, and
the electronic component module further includes a via in the insulating layer and bonded to the dummy electrode and the top surface of the integrated circuit.

10. The electronic component module according to claim 1,
wherein the second electronic component is an integrated circuit.

11. The electronic component module according to claim 1,
wherein the circuit board is an inorganic material substrate.

12. The electronic component module according to claim 11,
wherein the inorganic material substrate is a low-temperature co-fired ceramic substrate.

13. The electronic component module according to claim 2, further comprising a via in the insulating layer and connected to the input/output electrode but not to the columnar electrode.

14. The electronic component module according to claim 3, further comprising a via in the insulating layer and connected to the input/output electrode but not to the columnar electrode.

15. The electronic component module according to claim 2,
wherein the conductor is a via in each of the sealing resin layer and the insulating layer and includes an end along a side surface of the columnar electrode.

16. The electronic component module according to claim 3,
wherein the conductor is a via in each of the sealing resin layer and the insulating layer and includes an end along a side surface of the columnar electrode.

17. The electronic component module according to claim 4,
wherein the conductor is a via in each of the sealing resin layer and the insulating layer and includes an end along a side surface of the columnar electrode.

18. The electronic component module according to claim 2,
wherein the columnar electrode includes an end embedded in the insulating layer.

19. The electronic component module according to claim 3,
wherein the columnar electrode includes an end embedded in the insulating layer.

20. The electronic component module according to claim 4,
wherein the columnar electrode includes an end embedded in the insulating layer.
